(19) United States
(12) Patent Application Publication
(10) Pub. No.: US 2002/0194571 A1
(43) Pub. Date: Dec. 19, 2002

(54) System and method of coding cyclic redundancy check bits to enhance frequency reuse in a communications network

(76) Inventors: Michael Parr, San Diego, CA (US); Sharath Ananth, San Diego, CA (US); Vinayak Chowdiah, San Diego, CA (US)

Correspondence Address: Hughes Electronics Corporation, Patent Docket Administration, Bldg. 1, Mail Stop A109, P.O. Box 956, El Segundo, CA, 90245-0956, US

(21) Appl. No.: 09/974,651

(22) Filed: Oct. 10, 2001

Related U.S. Application Data
(60) Provisional application No. 60/297,983, filed on Jun. 13, 2001.

(51) Int. Cl. H03M 13/00

(52) U.S. Cl. 714/800; 714/781

(57) ABSTRACT

A system and method are provided for masking messages intended for a particular one of a plurality of receivers receiving messages on the same frequency in a satellite communication system. Each message contains a data portion and a parity portion. Before transmitting the message, the parity portion is masked by performing an exclusive-OR operation on the parity portion using a mask identified with the intended receiver. At the receiver, the parity portion of received messages are first unmasked by performing an exclusive-OR operation on the masked parity portion. The message is accepted by the receive only if the parity check is valid after the unmasking operation.

This application claims the benefit of U.S. Provisional Patent Appl. Ser. No. 60/297,983 filed Jun. 13, 2001 under 35 U.S.C. §119(e), the entire content of which is incorporated herein by reference.

### FIELD OF THE INVENTION

The following invention is related to a system and method for reducing interference between communications occurring on the same frequency in different beams of a satellite communications network. More particularly, the present invention is related to a system and method for distinguishing transmissions intended for a particular receiver in a frequency re-use environment of a satellite communications network.

### BACKGROUND OF THE INVENTION

Satellite telecommunications play an ever increasing role in satisfying society's communication needs. Because of the ever increasing demand for satellite resources, satellite bandwidth has become a precious commodity. As a result, various methods have been developed to maximize the efficiency of satellite resource use.

Typical satellite systems operate in a particular band of the electromagnetic spectrum. One known method of increasing a satellite system's ability to use a particular frequency band is known as frequency reuse. For example, one type of mobile satellite system comprises geosynchronous earth orbit (GEO) stationary satellites, which act as bent-pipe transmitters and receivers to enable various user terminals (UT's) in different parts of the world to communicate. The satellite system is generally only authorized to operate in a particular band of the electromagnetic spectrum. Therefore, the system takes advantage of frequency reuse to increase capacity. Each satellite illuminates the earth with different beams. The satellites each have multiple transmitters and receivers, which are each associated with a different beam. The beams are each shaped to cover a different geographic portion of the earth's surface. Because each beam only illuminates a particular portion of U.S. surface, frequencies within the allocated band of the electromagnetic spectrum are able to be reused in different beams. Thus, theoretically, if a message is transmitted from the satellite over one particular beam, only UTs within the footprint of the beam will receive the message. Similarly, when a UT transmits a message to the satellite, only the receiver associated with the beam covering the geographic area containing the UT should receive the message.

In practice, because the satellite receivers are extremely sensitive, a message transmitted by a user terminal within one beam is often received by multiple receivers at the satellite. This can result in multiple instances of the message being received and interpreted by the satellite communications system. As an example, if a user terminal within the beam wants to establish a call, typically a random access channel (RACH) message is transmitted. The RACH message is received by the system and interpreted as a request to establish a connection for a call. However, if the RACH message is received by two or more receivers at the satellite, the satellite system will interpret this as two or more separate requests for connections. This can inefficiently cause several allocations of satellite resources from the single user request.

In cellular systems, it is known to add identification bits to messages intended for a particular transceiver. However, because in the satellite system resources are extremely precious, it is undesirable to add any bits to the typical RACH message. Therefore, it is desirable to have a system and method for transmitting messages to a satellite having multiple receivers, such that the message could be identified, received and accepted only by the intended receiver. Furthermore, it is desirable to achieve such a system and method without adding any unnecessary bits to the RACH message.

### SUMMARY OF THE INVENTION

Accordingly, the above described disadvantages are overcome and other advantages are realized by providing a method and system for coding parity bits in a message to identify the message as intended for a particular receiver. At the transmitting end, a transmitter prepares a message comprising data bits and parity bits for transmission to a particular one of a plurality of receivers. The transmitter, before transmitting the message, performs a mathematical operation, such as an exclusive-OR operation, on the parity bits, using mask bits associated with the intended receiver. The resulting masked parity bits are appended to the data bits and transmitted as a masked message to the receiver. At the receiving end, the receiver receives the masked message comprising data bits and the masked parity bits. The receiver first performs an exclusive-OR operation on the masked parity bits using a set of masked bits associated with the receiver. If the receiver is the intended receiver, then the masked bits will match the masked bits used by transmitter. In this instance, the parity bits will be converted back to their original value. The receiver performs an ordinary parity check on the restored parity bits. If the parity check is valid, then the receiver accepts the message. If the receiver is one other than the intended receiver, then the receiver will apply masked bits which do not match the bits used to mask the parity bits of the original message. In this case, the parity bits will not be restored to their original value, and the parity check will fail, so that the message will be discarded or ignored.

### BRIEF DESCRIPTION OF THE DRAWINGS

These and other features and advantages of the present invention will be more readily appreciated from the following detailed description when read in connection with the appended drawings, which form a part of this original disclosure and wherein;

FIG. 1 is a diagram of a satellite system according to an embodiment of the present invention;

FIG. 2 illustrates a typical message having data bits and parity bits;

FIG. 3 illustrates the receipt of multiple instances of a message by multiple sensitive receivers;

FIG. 4 illustrates the formation of a masked message in accordance with an embodiment of the present invention;

FIG. 5 is a block diagram of a transmitter in accordance with an embodiment of the present invention;

FIG. 6 is a flow chart illustrating the functionality of a transmitter in accordance with an embodiment of the present invention;

FIG. 7 is a block diagram of a receiver constructed in accordance with an embodiment of the present invention;

FIG. 8 is a flow chart illustrating the functionality of a receiver constructed in accordance with an embodiment of the present invention; and

FIG. 9 illustrates the formation of unmasked messages at two different receivers, in accordance with an embodiment of the present invention.

In the figures it will be understood that like numerals refer to similar structures.

### DETAILED DESCRIPTION OF THE INVENTION

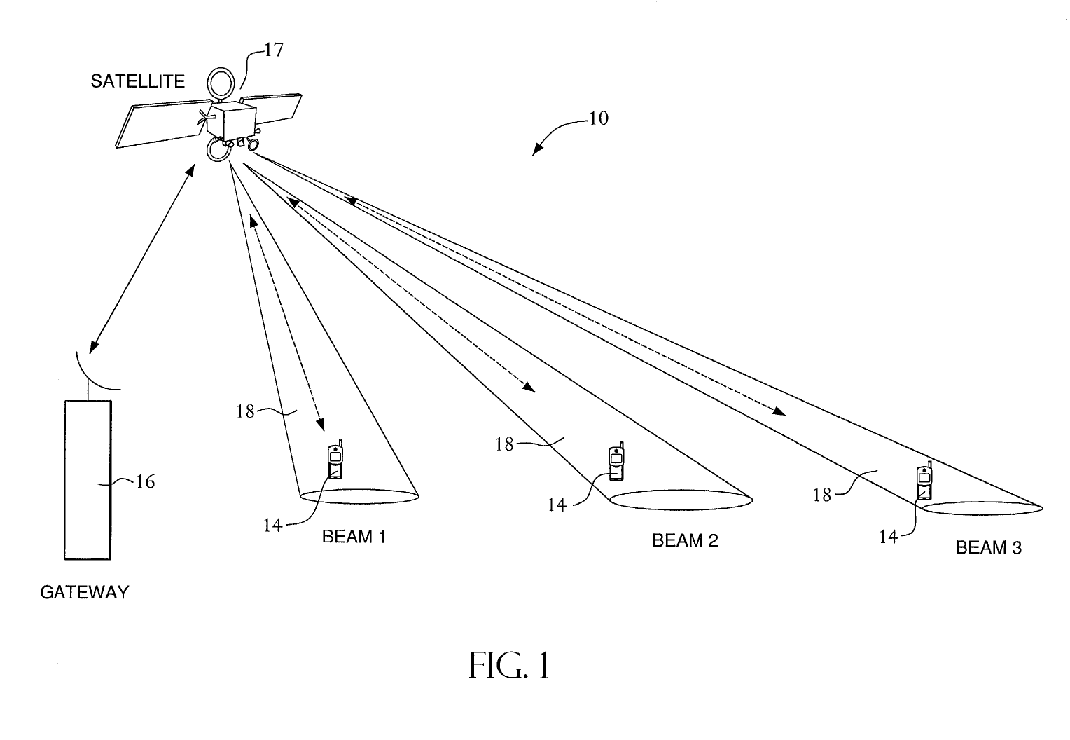

As illustrated in FIG. 1, a system 10 in accordance with an embodiment of the present invention comprises at least one satellite 12, several user terminals (UT) 14, and preferably at least one gateway 16. The satellite 12 preferably has a plurality a transmitters and receivers (not shown) which are capable of forming beams 18. For illustrative purposes, only three beams are shown, although it will be understood by those of skill in the art that a much greater number of beams could be utilized to increase the efficiency resulting from frequency reuse. As is known in the art, frequencies may be reused in different beams, although in TDMA systems preferably the same frequencies will not be reused in geographically adjacent beams. Thus, in a system as illustrated in FIG. 1, a first set of frequencies may be used in beam 1, a second set of frequencies will be used in beam two, and the first set of frequencies could be reused in beam 3. Of course those of skill in the art will recognize that the same frequencies may be reused in geographically adjacent beams, as in, for instance, a CDMA system. The present invention is not intended to be limited to systems that reuse frequencies only in geographically distinct beams, and those of ordinary skill in the art will appreciate that the present invention could be employed in systems, such as CDMA systems, which reuse frequencies in geographically adjacent beams.

In order to place a call, a user terminal (UT) typically transmits a connection request message (using the Random Access Channel, or RACH) over a common channel to request a connection to the satellite 12. The RACH messages is relayed by the satellite 12 to the gateway 16. The communications network (not shown) then allocates frequencies within beam one so that the user terminal requesting the connection can use the frequencies to place a call.

Because all user terminals 14 use the same channel for requesting connections, the RACH is preferably kept short to avoid collisions of messages from different UT's. Furthermore, because satellite resources in the common request channel are precious, it is undesirable to add any unnecessary bits to the RACH.

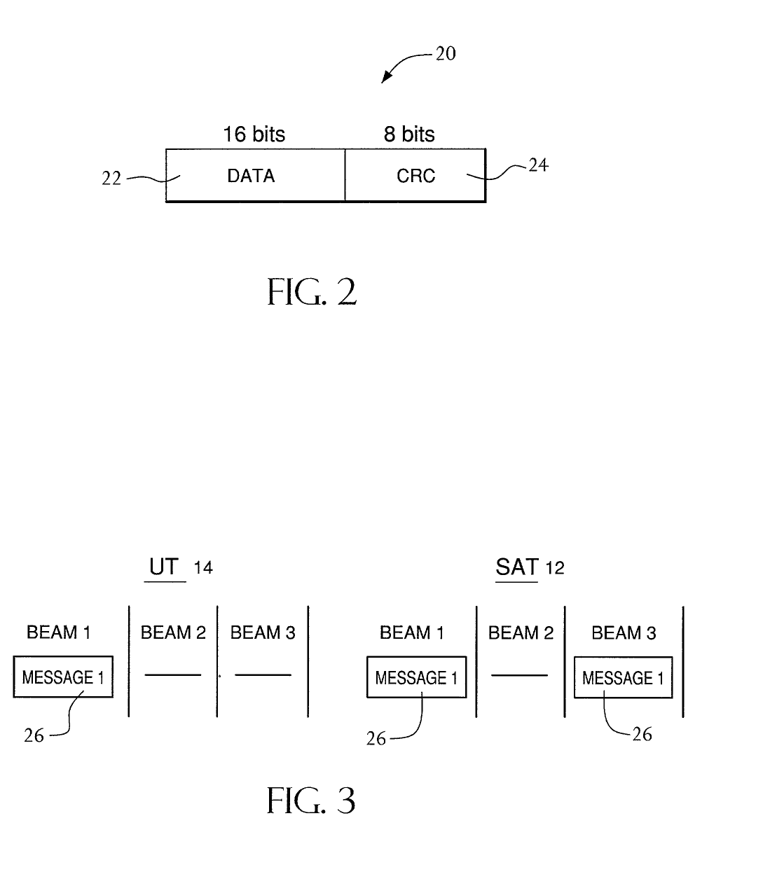

FIG. 2 illustrates an example of a RACH 20. The exemplary message 20 consists of a 16 bit data field 22 which is followed by an 8 bit cyclic redundancy check field (CRC) 24. Those of skill in the art will appreciate that the RACH message could be comprised of different numbers of bits without departing from the spirit and scope of the invention. The 8 bit CRC represents parity bits which provides the system with strong error detection and correction capabilities. Thus, when a system receives a RACH message 20, a parity check is done on the 8 CRC bits and the 16 data bits, and if the parity check is not valid, the message is ignored. Of course those of skill in the art will appreciate that the RACH message could be much longer than 16 bits, but have a particular subset of bits which are protected by a CRC field. In some cases, multiple CRC fields will protect distinct information fields. Such an approach is contemplated to be within the scope of the present invention.

Occasionally, it is possible that two or more user terminals will transmit a RACH 20 simultaneously. In the event of such a collision, it is possible that each of the RACH messages 20 will be corrupted, so that the CRC test fails, and each of the received messages will be ignored by the system. Because the RACH messages 20 are ignored, the user terminals 14 will not receive responses to the request messages 20, and each user terminal will retransmit the request message 20 after a random delay period. Thus, because of the randomly assigned delay prior, presumably each of the RACH messages 20 will be retransmitted at a different time, avoiding a recurring collision.

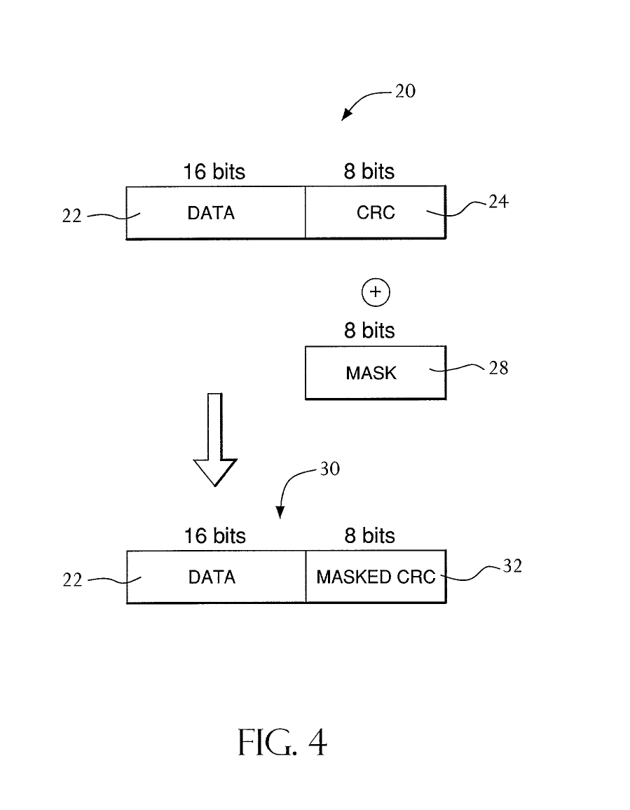

In a satellite communication system utilizing multiple beams and frequency reuse, as illustrated in FIG. 1, another possible problem arises. When a single user terminal transmits a RACH message 20, it is possible that the message will be received by more than one receiver (corresponding to more than one beam) because multiple receivers at the satellite are tuned to the same frequency. This situation is illustrated in FIG. 3. Message one 26 is transmitted by a user terminal located within beam 1. Because the multiple receivers at the satellite 12 are extremely sensitive, the receivers associated with beams 1 and 3, which are tuned to the same frequency ranges, both receive the transmitted message 26. Thus, as illustrated, two separate instances of message one are received and relayed by the satellite. It will be further understood that in a system having 30 or more separate beams using the same frequencies, this problem can be severely compounded.

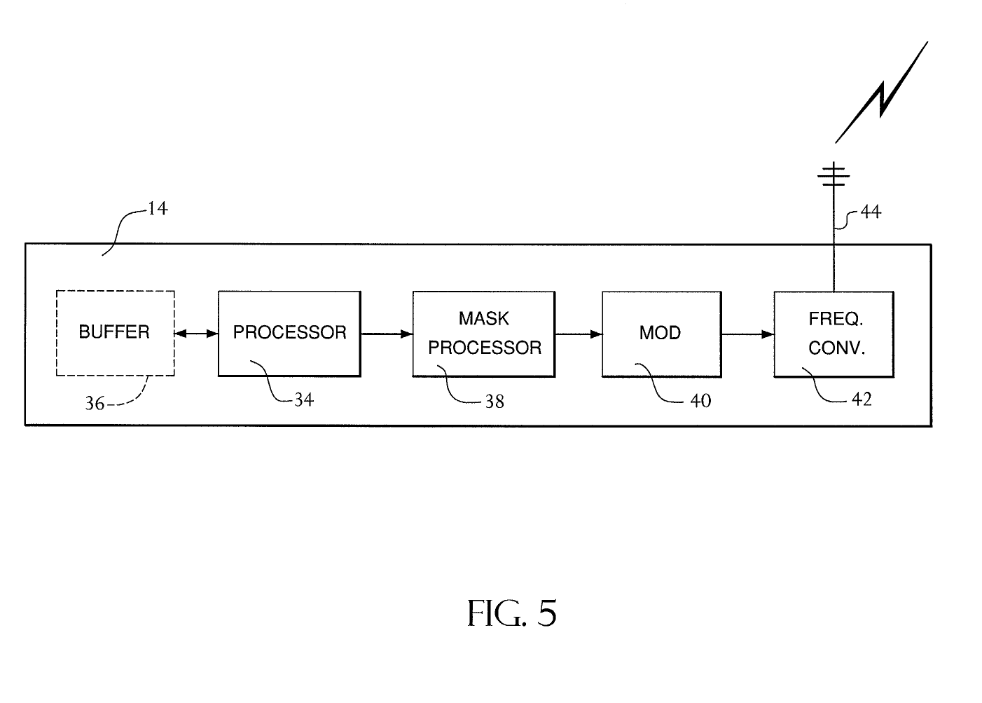

The above problem is overcome and other advantages are realized by providing a unique mask number to be associated with each beam and/or the receiver located at the satellite 12. The mask preferably has the same number of bits as the CRC in the RACH message 20. For illustrative purposes, the mask will be described as an 8 bit field. An 8-bit mask field will allow for up to 256 unique receivers. In accordance with an embodiment of the present invention, before transmitting a RACH message 20, the user terminal 14 performs an exclusive-OR operation on the CRC bits using the 8 bit mask associated with the intended receiver. This process is illustrated in FIG. 4. The original RACH message 20 comprising 16 data bits 22 and 8 CRC bits 24 is processed before being transmitted. The user terminal 14 (not shown) performs an exclusive-OR operation on the 8 CRC bits 24 using 8 mask bits 28 associated with the intended receiver. The result is a masked RACH message comprising the original 16 data bits 22 appended to 8 masked CRC bits 32. The masked message 30 is then transmitted to the satellite.

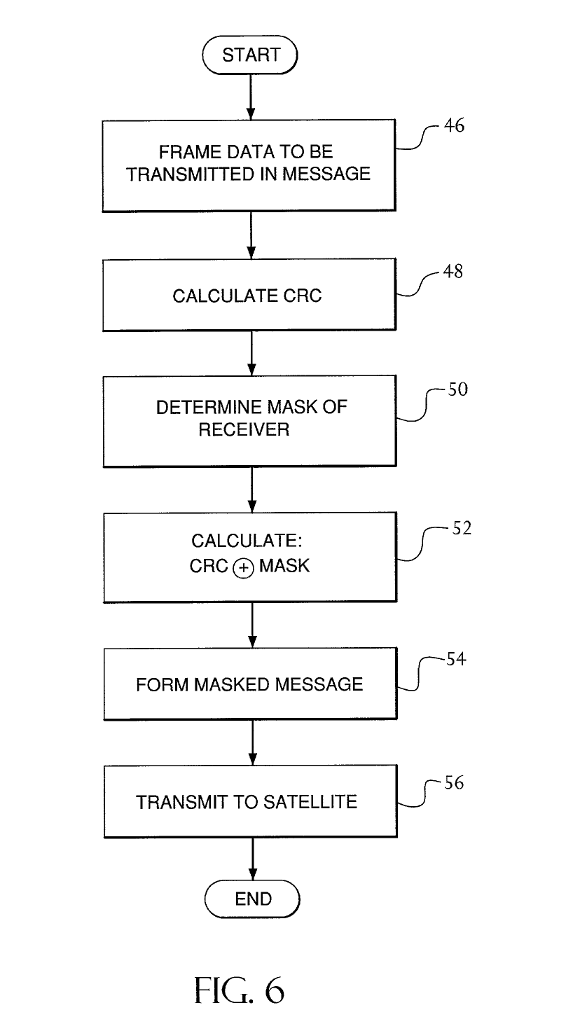

FIG. 5 illustrates a user terminal constructed in accordance with an embodiment of the present invention. The user terminal 14 comprises a processor 34 for forming messages to be transmitted to the satellite 12 (See FIG. 1). The processor is responsible for forming the messages as illustrated in FIG. 2. Thus, the processor assembles a 16 bit data field, and also calculates the 8 bit CRC field to be appended to the data field for error detecting and correction. The user terminal 14 further optionally contains a buffer 36 for storing data which can be accessed by the processor to be transmitted to the satellite 12. The processor is connected to a mask processor 38. The mask processor receives messages from the processor 34 and performs the masking operation to generate a masked message comprising a data field and a masked CRC field. The masked message is passed from the masked processor 38 to a modulator 40 which modulates the masked message so that it can be transmitted as a radio signal to the satellite 12. The user terminal 14 further comprises a frequency converter 42 which receives the modulated signal from the modulator 40 and converts it to a frequency assigned to the user terminal 14. Finally, the user terminal 14 has an antenna 44 for transmitting radio waves from the user terminal 14 toward the satellite 12.

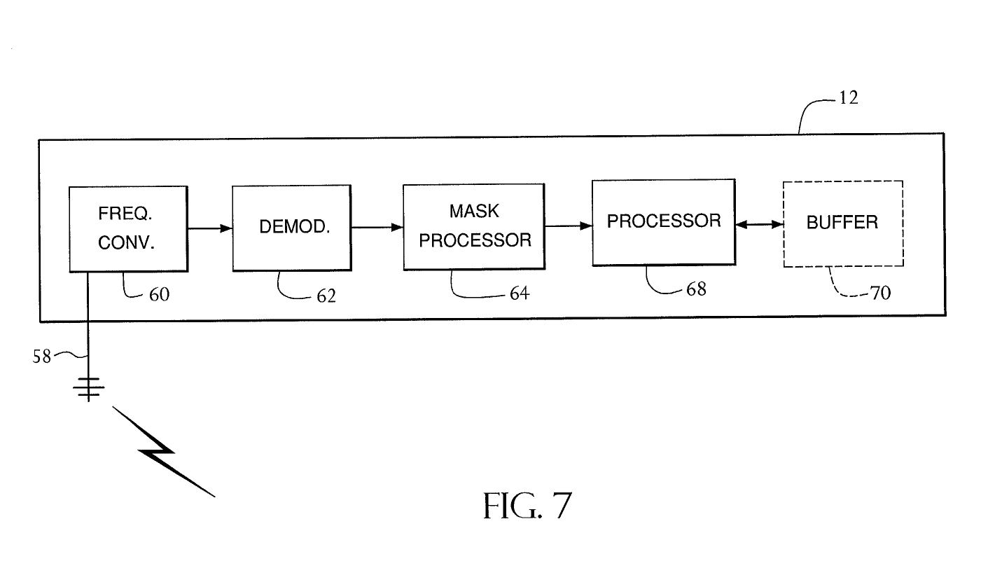

FIG. 6 illustrates the process of forming and transmitting messages in accordance with an embodiment of the present invention. First, the data to be transmitted in a single message is framed by the user terminal at step 46. A cyclic redundancy check value (CRC) is calculated based the data to be transmitted at step 48. At step 50, a mask which is associated with the intended receiver is determined. At step 52, a masked CRC is calculated. This is accomplished by performing an exclusive-OR operation during the CRC field calculator step 48 with the mask determined in step 50. It will be recognized by those of skill in the art that other operations may be used, however the exclusive-OR operation is preferred because exclusive-ORing a CRC twice using the same mask will restore the original CRC. At step 54 a masked message is formed from the data field and the masked CRC. Finally, at step 56 the masked message is transmitted to the satellite.

FIG. 7 is an illustration of a single receiver on board a satellite 12. It will be understood that there are typically a plurality of similar receivers on board a single satellite 12. Each receiver receives signals preferably from a single geographic area by using a directed beam as described above. The satellite 12 comprises a directional antenna 58 which receives signals from user terminals 14. The received signal is passed to a frequency converter 68 where the received signal is converted to base band. The base band signals are then passed to a demodulator 62 which demodulates the signals into individual masked messages. The individual masked messages are passed to a mask processor 64 which performs an unmasking operation on the masked message. The unmasking operation comprises performing an exclusive-OR operation on the masked CRC bits of the masked message using the mask associated with the particular receiver. This results in an unmasked message which is passed to the processor 68. The processor then performs a parity check on the unmasked message. If the parity check is valid, then the message is accepted and can be passed on for further processing. Also shown as an optional buffer 70 which can be used to store messages which have already been processed and are awaiting further processing. If the parity check preformed by the processor 68 is invalid, then the message can be ignored. Alternatively, it will be understood that a separate mask processor 64 may not be necessary, and the processor 68 can be programmed to perform the functions described above. Also, one of skill in the art will appreciate that the satellite may act simply as a bent pipe, and perform minimal processing on received signals, simply relaying signals to a gateway. In such an instance, which is contemplated to be within the scope of the invention, processing of the signal, including demodulation, masking or unmasking operations, parity checks, etc. are performed at the gateway, rather than on board the satellite.

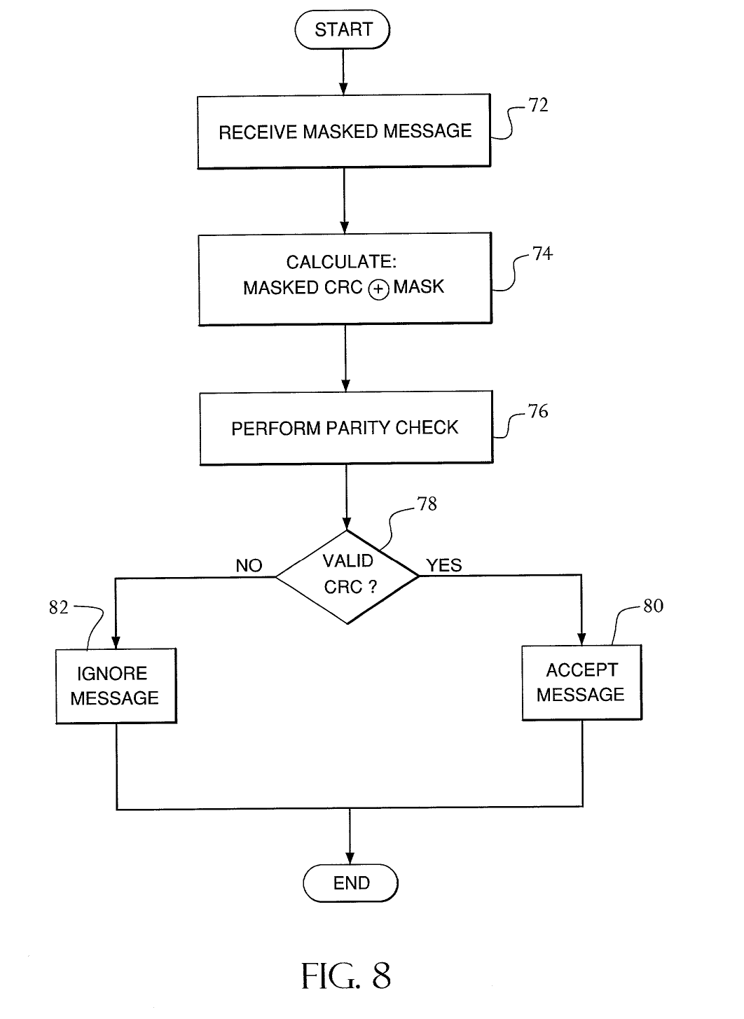

FIG. 8 illustrates the functionality of a receiver in accordance with the present invention. A masked message is received at 72. An unmasked CRC is calculated by performing an exclusive-OR operation on the masked CRC using the mask of the particular receiver at step 74. A parity check is performed on the unmasked message using the unmasked CRC at step 76. The unmasked CRC is determined to be valid or not at step 78, and if the CRC is valid, the message is accepted at step 80. Alternatively, if the CRC is invalid, the message can be ignored at step 82.

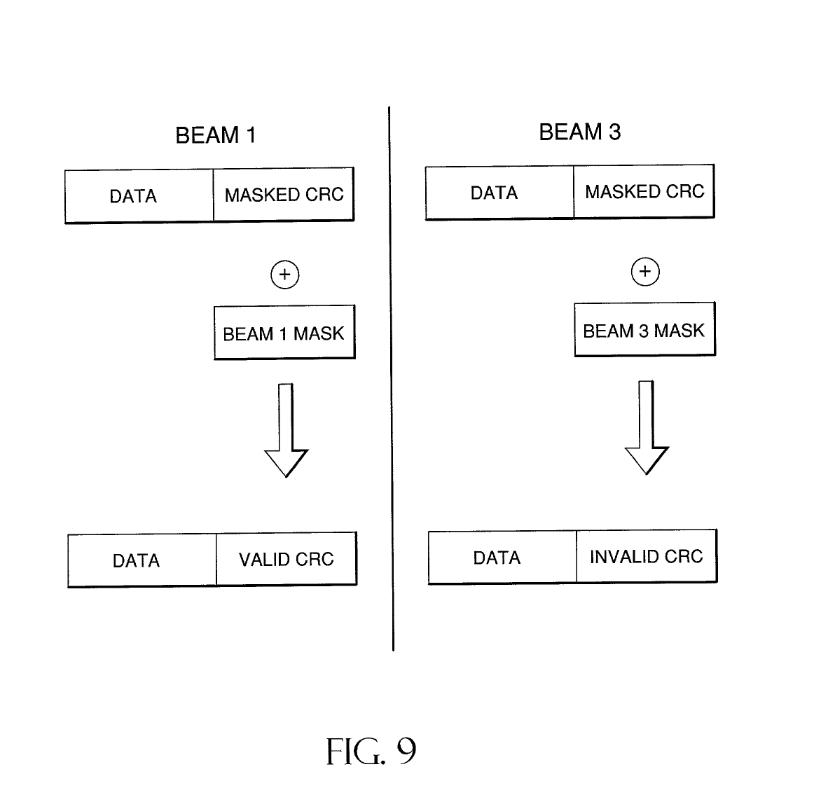

FIG. 9 illustrates two instances of a single message transmitted from a single UT 14 and received by two receivers corresponding to beam 1 and beam 3. The receivers for both beam 1 and beam 3 receive the message including the masked CRC field. The receiver associated with beam 1 performs an exclusive-OR operation on the masked CRC using the beam 1 mask. The receiver for beam 3 performs an exclusive-OR operation on the masked CRC using the mask for beam 3. Because the message was intended for the receiver in beam 1, the exclusive-OR operation performed by the receiver for beam 1 results in a valid CRC. This is because the initial valid CRC was originally masked at the user terminal 14 using an exclusive-OR operation using with same mask. Because the exclusive-OR operation is performed twice using the same mask, the original CRC is restored. Thus, the CRC is valid and the parity check will be valid so that the message is accepted. In beam 3, because the mask applied by the receiver to the masked CRC is different than the mask applied by the user terminal 14, the result of the exclusive-OR operation is an invalid CRC. Thus, the parity check will fail, and the message can be rejected.

In this manner, messages are transmitted to a particular receiver on a satellite, without adding any additional bits to the message. Even if the messages picked up by more than one receiver, only the receiver for which the message was intended will apply the correct mask, resulting in a valid CRC and a message which will be accepted. It will be understood by one of ordinary skill in the art that the preceding description described a system and method for processing a particular message, the RACH. However, the invention is not limited to RACH messages, and it is contemplated that the system and method of the present invention could be applied to other messages transmitted in a frequency reuse environment of a satellite communications network, having error detection and/or correction bits.

While certain advantageous embodiments have been chosen to illustrate the invention, it will be understood by those skilled in the art that various changes and modifications can be made herein without departing from the scope of the invention as defined in the appended claims.

What is claimed is:

1. A method of transmitting information to one of a plurality of receivers comprising:
preparing a message for transmission to a first receiver, said message comprising a first portion comprising data bits and a second portion comprising parity bits,
identifying a mask associated with said first receiver,
forming a masked parity portion by performing an operation on said second portion of said message using said mask,
forming a masked message comprising said first portion and said masked parity portion,
transmitting said masked message to said one of a plurality of receivers.

2. The method of claim 1, wherein said operation is an exclusive-OR operation.

3. A method of receiving information comprising:
receiving a masked message at a receiver from a remote terminal, said message comprising a first portion containing data bits and a masked parity portion containing masked parity bits,
forming an unmasked parity portion by performing an operation on said masked parity bits using a mask associated with said receiver,
checking the parity of said data bits using said unmasked parity portion,
accepting said masked message if said parity check is valid,
discarding said masked message if said party check is invalid.

4. The method of claim 3, wherein said operation is an exclusive-OR operation.

5. A system for transmitting information to a remote receiver comprising:
a transmitter adapted to transmit a message comprising a data portion and a parity portion to one of a plurality of receivers,
a processor connected to said transmitter, adapted to identify a mask associated with said one of a plurality of receivers, and further adapted to transform said parity portion of said message by performing an operation on said parity portion using said mask.

6. The system of claim 5, wherein said operation is an exclusive-OR operation.

7. A system for receiving messages from a remote transmitter comprising:
a receiver adapted to receive a masked message comprising a data portion and a masked parity portion,
a processor adapted to receive said message from said receiver and to perform an operation on said masked parity portion using a mask associated with said receiver to form an unmasked message,
a message filter adapted to perform a parity check on said unmasked message, and
to accept said message if said parity check is valid.

8. The systems of claim 7, wherein said operation is an exclusive-OR operation.

9. A computer readable medium of instructions for controlling a transmitter to transmit information to one of a plurality of receivers comprising:
a first set of instructions adapted to control said transmitter to prepare a message for transmission to a first receiver, said message comprising a first portion comprising data bits and a second portion comprising parity bits,
a second set of instructions adapted to control said transmitter to identify a mask associated with said first receiver,
a third set of instruction adapted to control said transmitter to form a masked parity portion by performing an operation on said second portion of said message using said mask,
a fourth set of instructions adapted to control said transmitter to form a masked message, said masked message comprising said first portion and said masked parity portion, and
a fifth set of instructions adapted to control said transmitter to transmit said masked message to said one of a plurality of receivers.

10. The computer readable medium of instructions according to claim 9, wherein said operation is an exclusive-OR operation.

11. A computer readable medium of instructions for controlling a receiver to receive information comprising:
a first set of instructions adapted to control said receiver to receive a masked message from a remote terminal, said masked message comprising a first portion containing data bits and a masked parity portion containing masked parity bits,
a second set of instructions adapted to control said receiver to form an unmasked parity portion by performing an operation on said masked parity bits using a mask associated with said receiver,
a third set of instructions adapted to control said receiver to check the parity of said data bits using said unmasked parity portion,
a fourth set of instructions adapted to control said receiver to accept said masked message if said parity check is valid, and
a fifth set of instructions adapted to control said receiver to discard said masked message if said party check is invalid.

12. The computer readable medium of instructions according to claim 11, wherein said operation is an exclusive-OR operation.
